(19) United States
(12) Patent Application Publication
(10) Pub. No.: US 2013/0224965 A1
(43) Pub. Date: Aug. 29, 2013

(54) SEMICONDUCTOR MANUFACTURING APPARATUS AND MANUFACTURING METHOD OF SEMICONDUCTOR DEVICE

(71) Applicant: Kabushiki Kaisha Toshiba, (US)

(72) Inventors: Takashi SASAKI, Mie-ken (JP); Hideto MATSUYAMA, Mie-ken (JP)

(73) Assignee: KABUSHIKI KAISHA TOSHIBA, Tokyo (JP)

(21) Appl. No.: 13/779,508

(22) Filed: Feb. 27, 2013

(30) Foreign Application Priority Data
Feb. 29, 2012 (JP) 2012-044803

(51) Int. Cl. H01L 21/02

(52) U.S. Cl. CPC H01L 21/02274
USPC 438/766; 118/723 R; 118/723 E; 118/723 I

(57) ABSTRACT

According to one embodiment, a semiconductor manufacturing apparatus, which forms a metal film, and which has the following parts: a processing chamber that carries out the processing of a substrate set inside it, a gas feeding part that feeds the feed gas of the metal film and a plasma generating gas into the processing chamber, a plasma generating part that generates the plasma of the plasma generating gas, and a bias generating part that causes the ions generated by the plasma generating part to impact on the substrate.

### CROSS-REFERENCE TO RELATED APPLICATION

This application is based upon and claims the benefit of priority from Japanese Patent Application No. 2012-044803, filed on Feb. 29, 2012, the entire contents of which are incorporated herein by reference.

### FIELD

Embodiments described herein relates generally to a semiconductor manufacturing apparatus and a manufacturing method of semiconductor device.

### BACKGROUND

As the semiconductor devices are being made finer and finer, in the manufacturing process, the technology of using metal materials as the wiring pattern and contacts on the semiconductor wafer as the workpiece for processing is becoming more and more important. Examples of the normally used metal materials include W (tungsten), WSi (tungsten silicide), Ti (titanium), TiN (titanium nitride), TiSi (titanium. silicide), Cu (copper), Ta2O5 (tantalum oxide), etc. The metals are deposited to form thin films.

Among the above-listed types of metals and metal compounds, the tungsten film is used more frequently since it has a low resistivity and a lower temperature for attaching the film. The tungsten film can be formed from WF6 (tungsten hexafluoride) used as the feed gas by reducing the feed gas using hydrogen, silane, dichlorosilane, etc.

When the tungsten film is to be formed on a substrate, if the tungsten film is directly formed on the substrate, the initial film is formed as a tungsten film including micro-crystals, so that the tungsten film formed on the initial film is also composed of grains with a small grain size, and hence the resistance rises. In order to solve the problem, one may use the following scheme: an amorphous layer is formed as the underlying layer and, on the amorphous layer, the tungsten film is formed so that it is possible to forma tungsten film with a large grain size and hence a low resistance.

### DESCRIPTION OF THE DRAWINGS

FIG. 1 is a cross-sectional view illustrating the constitution of the semiconductor manufacturing apparatus related to Embodiment 1.

FIG. 2 is a cross-sectional view illustrating the constitution of the semiconductor manufacturing apparatus in another example of Embodiment 1.

FIG. 3 is a manufacturing flow chart illustrating the manufacture of the semiconductor device using the semiconductor manufacturing apparatus in Embodiment 1.

FIG. 4 is a cross-sectional view illustrating a portion of the manufacturing process for producing the semiconductor device using the semiconductor manufacturing apparatus in Embodiment 1.

FIG. 5 is a cross-sectional view illustrating a portion of the process for manufacturing the semiconductor device using the semiconductor manufacturing apparatus in Embodiment 1.

FIG. 6 is a cross-sectional view illustrating a portion of the process for manufacturing the semiconductor device using the semiconductor manufacturing apparatus in Embodiment 1.

FIG. 7 is a schematic top view illustrating the multi-chamber type of film formation apparatus 30 as an example of the semiconductor manufacturing apparatus in Embodiment 2.

### DETAILED DESCRIPTION

In general, according to one embodiment, the semiconductor manufacturing apparatus can form a metal film; it includes a processing chamber that can carry out the processing of a substrate set in it, a gas feeding part that feeds the feed gas of the metal film and a plasma generating gas into the processing chamber, a plasma generating part that generates the plasma of the plasma generating gas, and a bias generating part that causes the ions generated by the plasma generating part to impact on the substrate.

There is provided a semiconductor manufacturing apparatus that can form a tungsten film with a low resistance and without restraint by the material of the underlying film, as well as a manufacturing method of a semiconductor device having the tungsten film.

### EMBODIMENT 1

In the following, Embodiment 1 will be explained with reference to figures.

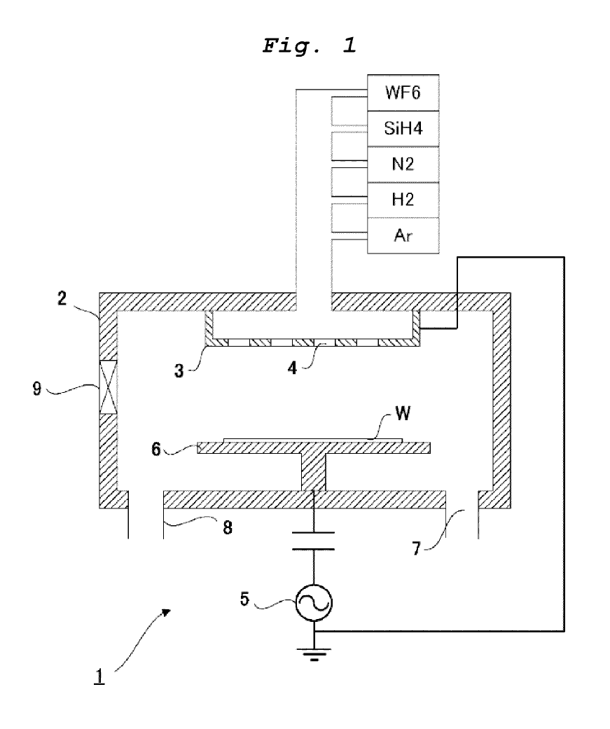

FIG. 1 is a cross-sectional view illustrating the constitution of the semiconductor manufacturing apparatus related to Embodiment 1. As shown in FIG. 1, the film forming apparatus 1 has a processing chamber 2 made of aluminum and having a nearly cylindrical cross-sectional shape. On the ceiling portion inside the processing chamber 2, a shower head part 3 is attached via an O-ring or other sealing part (not shown in the figure). It is for selectively feeding in various types of film forming gases and carrier gas, as well as the plasma generating gases, etc. The film forming gas is sprayed from the plural gas spraying ports 4 arranged on the lower surface of the shower head part towards the processing space.

In addition, the shower head part 3 may also have a structure wherein one or plural diffusing plates, each having plural diffusing holes, are arranged inside the shower head part so as to advance diffusion of the gas introduced therein. The shower head part 3 is connected with an RF power supply 5, so that it can be used as the upper electrode for generating plasma in the processing space.

In the processing chamber 2, a lower electrode 6 that can carry wafer W on it is arranged, formed from the bottom portion of the processing chamber. In addition to carrying the wafer W on it for film formation treatment, the lower electrode 6 also works as an electrode applied with a bias when the plasma processing of the wafer W is carried out. Below the lower electrode 6, a plural, for example, three, lifter pins (not shown in the figure) are arranged. As the lifter pins are driven to move up/down, the wafer W can be raised. Just as the shower head part 3, the lower electrode 6 is also connected with the RF power supply 5.

A gas exhausting port 7 is arranged in the peripheral edge of the bottom of the processing chamber 2. This gas exhausting port 7 is connected with a gas exhausting channel 8 connected to a vacuum pump not shown in the figure so that the interior of the processing chamber 2 can be evacuated to a certain vacuum level. Also, on the side wall of the processing chamber 2, a gate valve 9 is arranged so that it can be opened/closed when the wafer W is to be carried in/out.

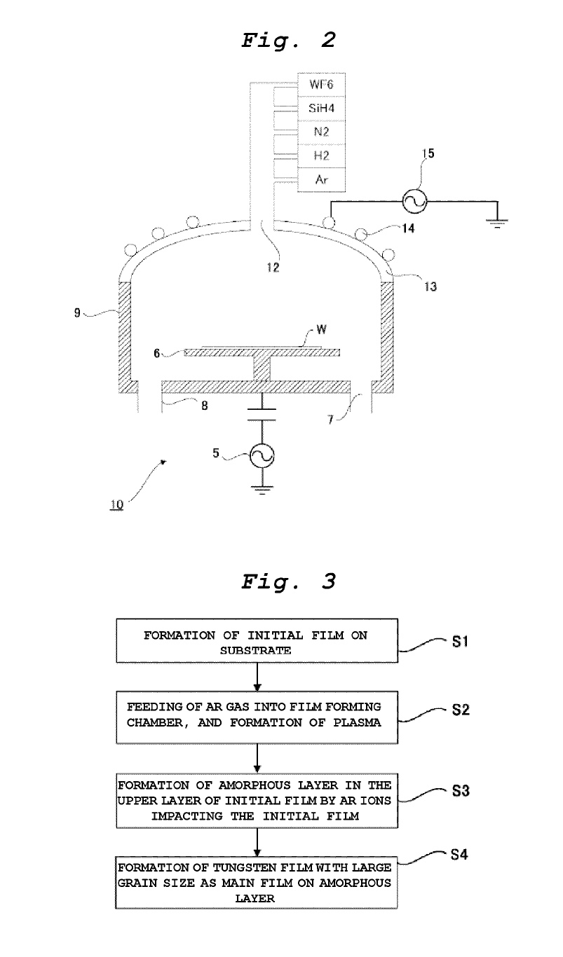

FIG. 2 is a cross-sectional view illustrating the constitution of the semiconductor manufacturing apparatus in another example of Embodiment 1. Different from the semiconductor manufacturing apparatus, which has a parallel plate type of electrode unit as the plasma generating mechanism, in the example shown in FIG. 2, an inductivity coupled plasma (ICP) mechanism is used to generate plasma.

As shown in FIG. 2, the film forming apparatus 10 has a processing chamber 11 made of aluminum and having a nearly cylindrical cross-sectional shape. On the ceiling portion inside the processing chamber 11, an inductive part 13 made of fused silica, ceramic or the like, and having a gas feeding port 12 is arranged. The gas feeding port is for selectively feeding in various types of film forming gases and carrier gas, as well as the plasma generating gas, etc. An inductive coil 14 is wound on the inductive part 13 for generating plasma, and it is connected with a power supply 15. The gas feeding port 12 may also have a structure wherein one or plural diffusing plates, each having plural diffusing holes, are arranged near the gas feeding port 12. In this way, diffusion of the gas fed in can be accelerated. The remaining features of the constitution are the same as those in FIG. 1, and the same keys as those in the above are used.

### (Manufacturing Method of Semiconductor Device)

First of all, the manufacturing method of a semiconductor device using the semiconductor manufacturing apparatus of Embodiment 1 will be explained. The gate valve 9 arranged on the side wall of the processing chamber 2 is opened, and wafer W is carried into the processing chamber 2 by a transporting arm not shown in the figure. The lifter pins are then raised to transfer the wafer W to the side of the lifter pins. The lifter pins are then lowered so that the wafer W is carried on the lower electrode 6.

FIG. 3 is a flow chart illustrating the manufacturing operation of a semiconductor device using the semiconductor manufacturing apparatus in Embodiment 1. First of all, an initial film 21 is formed on the substrate 20 (S1). There is no specific restriction on the material used for the initial film 21. However, in order to guarantee a low resistance, a film free of high-concentration boron or the like is preferred. According to the present embodiment, as shown in FIG. 4, the initial film 21 is formed from WF6 and SiH4 gas. Here, the metal film is formed by the ALD (atomic layer deposition) method.

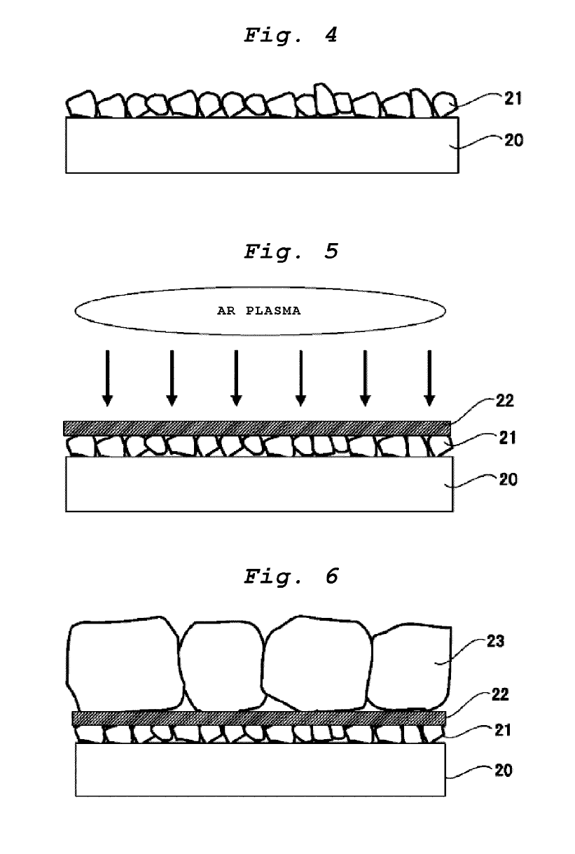

Next, Ar gas is fed into the processing chamber 2, and plasma is generated in the processing chamber 2 (S2). As shown in FIG. 5, a bias is then applied on the lower electrode 6 so that the Ar ions impact the initial film 21 to form an amorphous layer 22 in the upper layer of the initial film 21 (S3). In this embodiment, an amorphous layer is formed as ions impact on the initial film 21 that is exposed to the plasma. Consequently, the amorphous layer 22 can be formed without restriction on the material of the initial film 21.

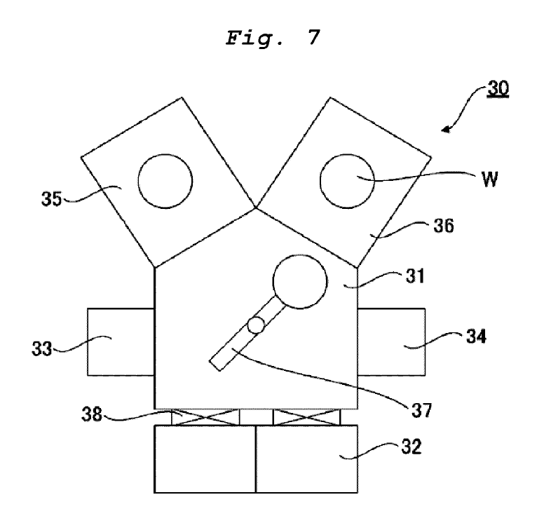

Next, as shown in FIG. 6, after formation of the amorphous layer 22, WF6 and H2 gases are fed into the processing chamber 2 to form a tungsten film 23 made of large grains as the main film (S4).

### EMBODIMENT 2

In the following, Embodiment 2 will be explained with reference to figures. Different from the semiconductor manufacturing apparatus in Embodiment 1 that has a means for generating plasma in the film forming chamber, in Embodiment 2, a semiconductor manufacturing apparatus having an independent plasma processing chamber separately arranged in the same apparatus will be explained.

FIG. 7 is a top view schematically illustrating the multi-chamber type of film formation apparatus 30 as an example of the semiconductor manufacturing apparatus in Embodiment 2. As shown in FIG. 7, the multi-chamber type of film formation apparatus 30 has a pentagonal shaped transporting chamber 31, with a loading port 32 arranged on one of its edges. As shown in FIG. 7, plural loading ports 32 may be arranged adjacent to each other. At the edges of the transporting chamber 31 facing each other as a pair, the first plasma processing chamber 33 and the second plasma processing chamber 34 are arranged, respectively. On the other hand, at the pair of oblique edges of the transporting chamber, the first film forming chamber 35 and the second film forming chamber 36 are arranged, respectively.

In the above, a multi-chamber type of film formation apparatus having two plasma processing chambers and two film forming chambers has been presented as an example. However, the present disclosure is not limited to this configuration, and the numbers of chambers may be selected appropriately.

Inside the transporting chamber 31, a transporting device 37 is arranged for transporting the wafer W into/out from the chamber. A load lock 38 is arranged between each loading port 32 and the transporting chamber 31.

### (Manufacturing Method of Semiconductor Device)

First of all, the manufacturing method of a semiconductor device using the semiconductor manufacturing apparatus of Embodiment 2 as discussed above will be explained. In order to facilitate explanation, a discussion will be conducted on the formation of tungsten or some other metal film in both the first film forming chamber 35 and the second film forming chamber 36.

First of all, the wafer W to be used in the formation of a metal film is fed to the loading port 32 from the state of accommodation wherein 25 wafers are accommodated as 1 lot in a hoop. The wafer W fed to the loading port 32 is picked up by the transporting device 37 via the load lock 38, then it is transported to the first film forming chamber 35 or the second film forming chamber 36.

The feed gas of the metal film is then fed into the film forming chamber to form a metal film on the wafer W. In this case, the metal film formed on the wafer W is the initial film with a small grain size. After the end of the film forming processing of the initial film, the wafer W is picked up from within the film forming chamber by the transporting device 37, and is transported to the plasma processing chamber. In this case, it may be transported to either the first plasma processing chamber 33 or the second plasma processing chamber 34. It is possible to select the appropriate chamber while plural wafers W can be processed at a high efficiency.

For the wafer W transported into the plasma processing chamber, as the Ar ions generated in the Ar plasma impact it, an amorphous layer is formed in the upper layer of the initial film. The wafer W is then transported from the plasma processing chamber and is transported again to the film forming chamber by the transporting device 37. Since an amorphous layer has been formed in the upper layer of the initial film of the wafer W transported into the film forming chamber again, when a metal film is formed on the amorphous layer, it is possible to form it as a low resistance film with a large grain size.

After formation of the low resistance film with a large grain size, the wafer W is picked up by the transporting device 37 and is transported from the film forming chamber. The wafer W transported from the cooling chamber is transported via the load lock 38 to the hoop set in the loading port 32.

As explained above, according to the present embodiment, a plasma processing chamber is arranged as a separate chamber in the metal film forming apparatus, so that an amorphous layer can be easily formed by simply transporting the wafer between the chambers after formation of the initial film, so it is possible to form a metal film as a low resistance with a large grain size on the amorphous layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. For example, upon forming the amorphous layer, it may be possible to form the plasma by using gas other than the Ar gas, and it is possible to use other materials as the initial film.

What is claimed is:

1. A semiconductor manufacturing apparatus for forming a metal film, comprising:
a processing chamber that carries out the processing of a substrate set therein,
a gas feeding part that feeds a feed gas of the metal film and a plasma generating gas into the processing chamber,
a plasma generating part that generates plasma of the plasma generating gas, and
a bias generating part that causes ions generated by the plasma generating part to impact on the substrate.

2. The semiconductor manufacturing apparatus according to claim 1, wherein
the plasma generating part generates plasma by parallel plate-type electrodes.

3. The semiconductor manufacturing apparatus according to claim 1, wherein
the plasma generating part generates the plasma by inductive coupling.

4. A manufacturing method of a semiconductor device comprising:
forming an initial film on a substrate,
exposing the substrate with the initial film formed thereon to plasma and impacting the ions generated by the plasma to the initial film to form an amorphous layer on the surface of the initial film, and
forming a metal film on the amorphous layer.

5. The manufacturing of a semiconductor device according to claim 4, wherein
the metal film is formed using the ALD method.

6. The manufacturing method of a semiconductor device according to claim 5, wherein
the metal film is a tungsten film that is formed from WF6 and SiH4 gas.

7. The manufacturing method of a semiconductor device according to claim 4, wherein
the initial film, the amorphous layer, and the metal film include a tungsten element.

8. The manufacturing method of a semiconductor device according to claim 4, wherein
the ions are Ar ions.

9. The manufacturing method of a semiconductor device according to claim 4, wherein
a grain size of the metal film is larger than that of the initial film.
